(19) United States
(12) Patent Application Publication
(10) Pub. No.: US 2025/0391756 A1
(43) Pub. Date: Dec. 25, 2025

(54) SELF-ALIGNED VIA CONNECTION WITH ENLARGED CONTACT AREA TO SUBTRACTIVE LINE

(71) Applicant: International Business Machines Corporation, Armonk, NY (US)

(72) Inventors: Koichi Motoyama, Clifton Park, NY (US); Ruilong Xie, Niskayuna, NY (US); Christopher J. Penny, Saratoga Springs, NY (US); Hosadurga Shobha, Niskayuna, NY (US); John Christopher Arnold, North Chatham, NY (US); Kisik Choi, Watervliet, NY (US)

(21) Appl. No.: 18/747,935

(22) Filed: Jun. 19, 2024

(51) Int. Cl. H01L 23/498

(52) U.S. Cl. CPC H01L 23/49827; H01L 23/49838

(57) ABSTRACT

A microelectronic interconnect structure that includes, a first metal line located at a first level, a second metal line located at a second level, wherein the first level and the second level are different levels, and a connecting via that connects the first metal line to the second metal line, wherein the connecting via includes a horizontal section and trench extenders, wherein the horizontal section is located on top of the first metal line, and the trench extenders extend down sidewalls of the first metal line.

### BACKGROUND

The present invention generally relates to the field of microelectronics, and more particularly to the contact area for via connections in an interconnect.

Establishing the connection between the two or more metal layers within a microelectronic structure often includes various processes, such as, but not limited to removal/etching and/or patterning/lithography. During these processes the alignments of the via connections may vary as a result of any number of inconsistencies during these processes.

### BRIEF SUMMARY

Additional aspects and/or advantages will be set forth in part in the description which follows and, in part, will be apparent from the description, or may be learned by practice of the invention.

A microelectronic interconnect structure that includes, a first metal line located at a first level, a second metal line located at a second level, wherein the first level and the second level are different levels, and a connecting via that connects the first metal line to the second metal line, wherein the connecting via includes a horizontal section and trench extenders, wherein the horizontal section is located on top of the first metal line, and the trench extenders extend down sidewalls of the first metal line.

A microelectronic interconnect structure that includes, a first metal line located at a first level, a second metal line located at a second level, wherein the first level and the second level are different levels, and a connecting via that connects the first metal line to the second metal line, wherein the connecting via includes a lower horizonal section, a upper horizontal section, and trench extenders, wherein the lower horizontal section is located on top of the first metal line, wherein the trench extenders extend down sidewalls of the first metal line, wherein the upper horizontal section is located on the lower horizontal section, wherein the upper horizontal section has a first width located on a first side of a reference axis, wherein the reference axis is located vertically through the center of the first metal line, wherein the upper horizontal section has a second width located on a second side of a reference axis, and wherein the first width and the second width are different.

A microelectronic interconnect structure that includes, a plurality of lower metal lines located at a first level, a plurality of upper metal lines located at a second level, wherein the first level and the second level are different levels, and a plurality of connecting vias where each of the plurality of connecting via connects one of the plurality of the first metal lines to one of the plurality of the second metal lines, wherein each of the plurality of connecting vias includes a horizonal section and trench extenders, wherein the trench extenders for each of the plurality of connecting via extends down sidewalls of each of the plurality of first metal lines, respectively.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a microelectronic structure prior to initial processing including a hardmask, a first metal layer, a metal adhesion liner, and an underlying device, in accordance with the embodiment of the present invention.

FIG. 2 illustrates the microelectronic structure after patterning of the metal layer, in accordance with the embodiment of the present invention.

FIG. 3 illustrates the microelectronic structure after formation of the dielectric liner, in accordance with the embodiment of the present invention.

FIG. 4 illustrates the microelectronic structure after the formation of a sacrificial protection layer, in accordance with the embodiment of the present invention.

FIG. 5 illustrates the microelectronic structure after the removal of portions of the dielectric liner, in accordance with the embodiment of the present invention.

FIG. 6 illustrates the microelectronic structure after the removal of the lithography layer, and the formation of a dielectric layer, in accordance with the embodiment of the present invention.

FIG. 7A illustrates the microelectronic structure after the formation and patterning of the lithography layer in an ideal alignment scenario, in accordance with the embodiment of the present invention.

FIG. 7B illustrates the microelectronic structure after the formation and patterning of the lithography layer in a misalignment scenario, in accordance with the embodiment of the present invention.

FIG. 8A illustrates the microelectronic structure after hardmask removal in the ideal alignment scenario, in accordance with the embodiment of the present invention.

FIG. 8B illustrates the microelectronic structure after hardmask removal in the misalignment scenario, in accordance with the embodiment of the present invention.

FIG. 9A illustrates the microelectronic structure after dielectric liner removal in the ideal alignment scenario, in accordance with the embodiment of the present invention.

FIG. 9B illustrates the microelectronic structure after dielectric liner removal in the misalignment scenario, in accordance with the embodiment of the present invention.

FIG. 10A illustrates the microelectronic structure after the removal of the lithography layer, a metallization process, and separation process to form a plurality of metal lines in the ideal alignment scenario, in accordance with the embodiment of the present invention.

FIG. 10B illustrates the microelectronic structure after the removal of the lithography layer, a metallization process, and separation process to form a plurality of metal lines in the misalignment scenario, in accordance with the embodiment of the present invention.

FIG. 11 illustrates the microelectronic structure after the forming of via connections in both ideal alignment and misalignment scenarios, in accordance with at least one embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like.

Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards an interconnect that includes multiple metal level/layers/lines/planes and metal connecting vias. The metal connecting vias form an electrical connection between two or more layers, for example, a first metal line (Mx) located on a first level and a second metal line (Mx+1) located on a second level.

A via is an electrical connection between two or more metal layers/lines/levels/planes. The lower the resistance between the two or more metal layers, the higher the current flow. The surface contact area—affects the resistance between components.

Forming via connections with an increased surface contact area can be challenging, such that, the via connections can be formed in an ideal alignment scenario, a misalignment scenario, and/or combinations thereof. The present invention addresses the challenges in forming via connections in all the above scenarios by increasing the contact surface area between the self-aligned via and the metal line below, lower the resistance and increasing the current flow. This is achieved by removing the hardmask and a portion of the dielectric liner surrounding the first metal (Mx) line. The removal of the hardmask forms a trench and the removal of the portion of the dielectric liner extends the trench to expose a portion of the sidewalls on each side of the first metal (Mx) line. The depths of the removed dielectric liner and the exposed portions of the sidewalls depicted in the Figures are meant to be illustrative and in no way limit the scope of the present invention. The trench and the trench extenders are then filled with a conductive metal during a metallization process forming the via connection, which connects the first metal (Mx) line of a first layer/level with the second metal (Mx+1) line of a second layer/level. The connecting via wraps around the top and extends down the sidewalls of the first metal (Mx) line increasing the surface contact between the connecting via and the first metal (Mx) line, enabling higher current flow and lower resistance to be achieved in ideal alignment scenarios, misalignment scenarios, and/or combinations thereof.

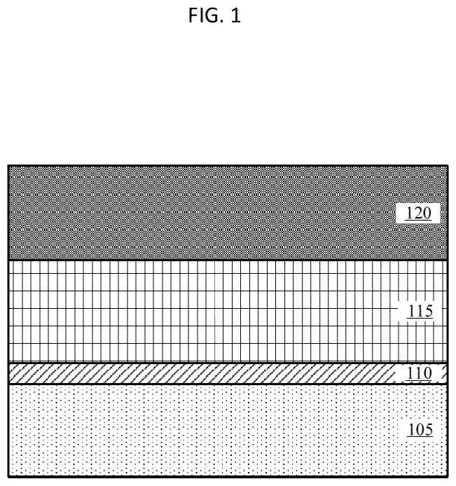

FIG. 1 illustrates a microelectronic structure prior to initial processing including an underlying device 105, a metal adhesion liner 110, a first metal layer 115, and a hardmask 120. The underlying device 105 can be, for example, a logic device, a memory device, a passive device, or any other type of electronic device that may require an interconnect. The metal adhesion liner 110 is formed on top of the underlying device 105 and may be comprised of metals, metal nitride, and metal oxide, such as, but not limited to, Tantalum Nitride (TaN) or Titanium Nitride (TiN). The first metal layer 115 is formed on top of the metal adhesion liner 110 and may be comprised of, for example, Cu, Co, Ru, W, Mo, Rh, Ir, Ni, Al, or conductive alloy/one or more platinum group metals, other suitable conductive metal, or any combination thereof. The hardmask 120 is formed on top of the first metal layer 115. The hardmask 120 may be a protective layer that is selectively etchable. The hardmask 120 is formed on top of the first metal layer 115. The hardmask 120 may be a protective layer that is selectively etchable. As will be explained in greater detail below, the hardmask 120 can be utilized as an etching mask during the fabrication process for self-aligned via performance. The hardmask 120 may be comprised of Silicon Nitride (SiN), Titanium Nitride (TiN), or Silcon Oxynitride (SiON), amongst other suitable hardmask materials.

FIG. 2 illustrates the microelectronic structure after patterning of the metal adhesion liner 110, the first metal layer 115, and the hardmask 120. The metal adhesion liner 110, the first metal layer 115, and the hardmask 120 are patterned to form a plurality of lines. The first metal layer 115 is separated into a plurality of metal (Mx) lines 116 (also referred to a first Mx line 116 located at a first layer/level/plane). Each of the plurality of metal lines 116 has a metal adhesion liner 110 below and hardmask 120 on top after patterning which is performed by one or more removal/etching processes. Examples of the one or more removal/etching processes which can be utilized include, but are not limited to including, etching process (either wet or dry), reactive ion etching (RIE), chemical-mechanical polishing, amongst other isotropic etching/removal processes to pattern the metal adhesion liner 110, the first metal layer 115, and the hardmask 120 and separate/form the plurality of lines.

FIG. 3 illustrates the processing stage after the formation of the dielectric liner 125. The dielectric liner 125 is formed on top of or along the exposed surfaces of the hardmask 120, the plurality of metal lines 116 (Mx lines located at a first level), the metal adhesion liner 110, and the underlying device 105.

FIG. 4 illustrates the processing stage after the formation of a sacrificial protection layer. The sacrificial protection layer may be a lithography layer 130 which is formed on top of the dielectric liner 125. The lithography layer 130 is pulled down to expose a portion of the dielectric liner 125 located adjacent to the hardmask 120.

FIG. 5 illustrates the processing stage after the removal of portions of the dielectric liner 125. The portion of the dielectric liner 125 removed is the portion of the dielectric liner 125 exposed by pulling down the lithography layer 130, as described in FIG. 4. The lithography layer prevents the over-removal of the dielectric liner 125. The removal of the exposed portion of the dielectric liner 125 exposes a portion of the hardmask 120, as emphasized by dashed box 135. The removal of the exposed portion of the dielectric liner 125 can be performed utilizing one or more removal/etching processes to selectively remove the portions of the dielectric liner 125 including, but are not limited to including, etching process (either wet or dry), reactive ion etching (RIE), chemical-mechanical polishing, amongst other isotropic etching/removal processes.

FIG. 6 illustrates the processing stage after the removal of the lithography layer 130, the formation of an interlayer dielectric (ILD) 140, and chemical mechanical planarization (CMP). The lithography layer 130 is removed utilizing one or more removal/etching processes. The ILD 140 is formed around the dielectric liner 125 and the exposed portion of the hardmask 120 enclosing each of the plurality of metal lines 116 and metal adhesion liners 110. Excess of the ILD 140 is removed by CMP to expose the top surface of the hardmask 120.

FIG. 7A illustrates the processing stage after the formation and patterning of lithography layer 145 in an ideal alignment scenario. In the ideal alignment scenario, the removal/etching of the lithography layer 145, emphasized by dashed box 123, results in equal or similar length spacing to the left and the right of the top of the now exposed hardmask 120 as emphasized by dashed brackets W1 and W2.

FIG. 7B illustrates the processing stage after the formation and patterning of the lithography layer 145 in a misalignment scenario. In the misalignment scenario, the removal/etching of the lithography layer 145, emphasized by dashed box 127, results in different or dissimilar length spacing to the left and right of the top of the now exposed hardmask 120 as emphasized by dashed brackets W3 and W4. Although, FIG. 7B illustrates W3 with a greater length than W4 in other embodiments W4 may be greater in length than W3.

FIG. 8A illustrates the processing stage after removal of the hardmask 120 and a portion of the ILD 140 layer in the ideal alignment scenario. The hardmask 120 and the portion of the ILD 140 layer are removed to form a via 205 that exposes a top of the metal line 116A (e.g., metal line 116A of a first level) and side portions of the dielectric liner 125 surrounding the metal line 116A. As will be explained in greater detail with respect to at least FIGS. 9A and 10A, the metal line 116A is one of the plurality of metal lines 116 of the first level for which a connection will be established with a metal line of a second level.

FIG. 8B illustrates the processing stage after the removal of the hardmask 120 and a portion of the ILD 140 layer in the ideal alignment scenario. The hardmask 120 and the portion of the ILD 140 layer are removed to form a trench 207 that exposes a top of the metal line 116B (e.g., metal line 116B of a first level) and side portions of the dielectric liner 125 surrounding the metal line 116B. As will be explained in greater detail with respect to at least FIGS. 9B and 10B, the metal line 116B is one of the plurality of metal lines 116 of the first level for which a connection will be established with a metal line of a second level.

FIG. 9A illustrates the processing stage after removing a portion of the dielectric liner 125 in the ideal alignment scenario. Portions of the dielectric liner 125 are selectively removed by etching to form trench extenders 210 (e.g., via extenders 210). The trench extenders 210 extend off of trench 205. The trench extenders 210 expose a portion of the sidewalls of the metal line 116A (e.g., metal line 116A of the first level). The depth of the trench extenders 210 formed may differ according to one or more variations in the fabrication process which may lead to varying exposed portions of the sidewalls of the metal line 116A. The portion of the sidewalls of the metal line 116A that are exposed are illustrated by brackets 115E and 115E2 and the portion of the sidewalls of the metal line 116A that are covered are illustrated by brackets 115C and 115C2. As described above, the depth of the trench extenders 210 may vary according to variations in the portions of the dielectric liner 125 removed during the fabrication process which may correspond to different portions of the sidewalls being exposed from those illustrated by brackets 115E and 115E2. The depths of the trench extenders 210 (e.g., via extenders 210) formed by the removal of the dielectric liner 125 in FIG. 9A in no way limit the scope of the present invention, and the length of brackets 115E and 115E2 may each vary according to different variations in the fabrication process for the idea alignment scenario. The exposed sidewall illustrated by bracket 115E may be longer, shorter, or the same length in different embodiments of the ideal alignment scenario according to variations in the fabrication process. Additionally, the exposed sidewall illustrated by bracket 115E may be longer, shorter, or the same length as the exposed sidewall on the other side of the metal line 116A as illustrated by bracket 115E2. Accordingly, the portion of the sidewalls covered, as illustrated by brackets 115C2 and 115C may also vary on each side of the meal line 116A.

FIG. 9B illustrates the processing stage after removing a portion of the dielectric liner 125 in the misalignment scenario. Portions of the dielectric liner 125 are selectively removed by etching to form trench extenders 213 (e.g., via extenders 213). The trench extenders 213 extend off of trench 207. The trench extenders 213 expose a portion of the sidewalls of the metal line 116B (e.g., metal line 116A of the first level). The depth of the trench extenders 213 formed may differ according to one or more variations in the fabrication process which may lead to varying exposed portions of the sidewalls of the metal line 116B. The portion of the sidewalls of the metal line 116B that are exposed are illustrated by brackets 117E and 117E2 and the portion of the sidewalls of the metal line 116B that are covered are illustrated by brackets 117C and 117C2. As described above, the depth of the trench extenders 213 may vary according to variations in the portions of the dielectric liner 125 removed during the fabrication process which may correspond to different portions of the sidewalls being exposed from those illustrated by brackets 117E and 117E2. The depths of the trench extenders 213 (e.g., via extenders 213) formed by the removal of the dielectric liner 125 in FIG. 9B in no way limit the scope of the present invention, and the length of brackets 117E and 117E2 may each vary according to different variations in the fabrication process for the misalignment scenario. The exposed sidewall illustrated by bracket 117E may be longer, shorter, or the same length in different embodiments of the misalignment scenario according to variations in the fabrication process. Additionally, the exposed sidewall illustrated by bracket 117E may be longer, shorter, or the same length as the exposed sidewall on the other side of the metal line 116B as illustrated by bracket 117E2. Accordingly, the portion of the sidewalls covered, as illustrated by brackets 117C2 and 117C may also vary on each side of the meal line 116B.

FIG. 10A illustrates the processing stage after the removal of the lithography layer 145, a metallization process, and a separation process, in the ideal alignment scenario. The metallization process forms the connecting via 155V that connects the first metal line 116A located at the first level (e.g., metal line 116A) with the metal line 155B of another level (e.g., metal line 155B, second metal line 155B located at a second level). The metal line 155B may be located at a second level, third level, fourth level, or any other different level from the metal line 116A of the first level. The metallization process forms the connecting via 155V that connects the metal line 116A with the metal line 155B by filling the trench 205 and the trench extenders 210 (e.g., via extenders 210) with a conductive metal. The connecting via 155V wraps around the top of the metal line 116A. The connecting via 155V is in contact with a top surface of the metal line 116A and extends down the sidewalls of the metal line 116A, as emphasized by dashed box 215. The connecting via 155V includes a horizontal section and trench extenders 215M1, 215M2. The horizontal section has an hourglass shape/profile and is located on top of the first metal line 116A of the first level. The hourglass shape/profile of the horizontal section of the connecting via 155V has a similar/the same shape/width/dimensions on both sides of a central axis (A) extending through the metal line 116A. The upper half/portion of the hourglass shape/profile of the connecting via 155V is emphasized by dashed boxes 235W1, 235W2, which in combination form the upper level of the connecting via 155V. The trench extenders 215M1, 215M2, extend down to the top of the dielectric liner 125 extending up the sidewalls of metal line 116A.

By having the trench extenders 215M1, 215M2 of the connecting via 155V wrap around and extend down the sidewalls of the metal line 116A, the surface contact between the connecting via 115V and the metal line 116A is increased when compared to a via just connecting with a top surface of a metal line. The increased surface contact between the connecting via 155V and the metal line 116A enables a higher current flow and lower resistance between the metal line 116A of the first level and the metal line 155B of the other level.

As described above in the discussion of FIG. 9A, the manufacturing process can lead to variations to the length/depth/height/dimension of the trench extenders 210 (e.g., the amount dielectric liner 125 that is removed, e.g., via extenders 210). Accordingly, the length/depth/height/dimension of the downwards extending fingers (the trench extenders 210 following metallization) of the connecting via 155V, as emphasized by brackets 215M1 and 215M2, may vary within the connecting via 155V, between different connecting vias 155, or any combination thereof.

In the ideal alignment scenario, as illustrated in FIG. 10A, the width/lateral dimension of the connecting via 155V is equal or similar to each other located on both sides of an axis (A), as emphasized by dashed boxes 235W1 and 235W2. The upper half of the hourglass shape/profile of the connecting via 155V is emphasized by dashed boxes 235W1, 235W2, which in combination form the upper level of the connecting via 155V.

The connecting via 155V connects metal line 116A located on a lower level/first level with the metal line 155B located on an upper level/second level. The conductive metal utilized for the metal line 155B, 155A of the upper level may be the same or different than the conductive metal utilized in the metal lines 116, 116A. The metal line 155B and the metal line 155A were formed from a common metal layer that was separated into multiple metal lines (e.g., metal lines 155A, 155B). A dielectric separator 141A is located between the metal lines 155A, 155B. The alignment of the dielectric separator 141A determines the overlay of the tips of the metal lines 155A, 155B and one of underlying hardmask layers 120, as emphasized by dashed box 219A. FIG. 10A illustrates where the dielectric separator 141 is properly aligned, such that tips of the metal lines 155A, 155A are spaced apart from the hardmask 120, as emphasized by dashed box 219A.

FIG. 10B illustrates the processing stage after the removal of the lithography layer 145, a metallization process, and a separation process, in the misalignment scenario. The metallization process forms the connecting via 155V that connects the metal line 116B located at the first level (e.g., metal line 116B, a first metal line 116B located the first level) with the metal line 155B located at another level (e.g., metal line 155B, second metal line 155B located at a second level). The metal line 155B may be located at a second level, third level, fourth level, or any other different level from the metal line 116B of the first level. The metallization process forms the connecting via 155V that connects the metal line 116B with the metal line 155B by filling the trench 207 and the trench extenders 213 (e.g., via extenders 213) with a conductive metal. The connecting via 155V wraps around the top of metal line 116B. The connecting via 155V is in contact with a top surface of the metal line 116B and extends down the sidewalls of the metal line 116B, as emphasized by dashed box 217. The connecting via 155V includes an upper horizontal section, a lower horizontal section, and trench extenders 217M1, 217M2. The lower horizontal section is located on top of the metal line 116B of the first level. The trench extenders 217M1, 217M2 (e.g., via extenders) extend from the lower horizontal section of the connecting via 155V to the top of the dielectric liner 125 extending up the sidewalls of the metal line 116B. The upper horizontal section is located on top of the lower horizontal section. The upper horizontal section has a first width 245W1 located on a first side of a central axis (A) and a second width 245W2 located on a second side of the central axis (A), wherein the first width 245W1 is different than the second width 245W2. Although FIG. 10B depicts a wider first width 245W1 in comparison to the second width 245W2 in other embodiments the second width 245W2 may be wider than the first width 245W1.

By having the trench extenders 217M1, 217M2 of the connecting via 155V wrap around and extend down the sidewalls to the top of dielectric liner 125 of the metal line 116B, the surface contact between the connecting via 155V and the metal line 116B is increased when compared to a via just connecting with a top surface of a metal line. The increased surface contact between the connecting via 155V and the metal line 116B enables a higher current flow and lower resistance between the metal line 116B of the first level and the metal line 155B of the other level.

As described above in the discussion of FIG. 9B, the manufacturing process can lead to variations to the length/depth/height/dimension of the trench extenders 213 (e.g., the amount dielectric liner 125 that is removed, via extenders 213). Accordingly, the length/depth/height/dimension of the downwards extending fingers (the trench extenders 213 following metallization) of the connecting via 155V, as emphasized by brackets 217M1 and 217M2, may vary within the connecting via 155V, between different connecting vias 155, or any combination thereof.

In the misalignment scenario, as illustrated in FIG. 10B, the width/lateral dimension of the upper horizontal section of the connecting via 155V is unequal or dissimilar to each other on the first side 245W1 of a central axis (A) in comparison to the second side 245W2 of the central axis (A), the central axis (A) extending down the center of the metal line 116B.

The connecting via 155V connects metal line 116B located on a lower level/first level with the metal line 155B located on an upper level/second level. The conductive metal utilized for the metal line 155B, 155A of the upper level may be the same or different than the conductive metal utilized in the metal lines 116, 116A. The metal line 155B and the metal line 155A were formed from a common metal layer that was separated into multiple metal lines (e.g., metal lines 155A, 155B). A dielectric separator 141B is located between the metal lines 155A, 155B. The alignment of the dielectric separator 141B determines the overlay of the tips of the metal lines 155A, 155B and one of underlying hardmask layers 120, as emphasized by dashed box 219B. FIG. 10B illustrates where the dielectric separator 141 misaligned, such that tips of the metal lines 155B overlaps with the hardmask 120 and the metal lines 155A are spaced apart from the hardmask, as emphasized by dashed box 219B.

FIG. 11 illustrates the process stage after forming a plurality of connecting vias 155V. The plurality of connecting vias 155V are formed after the removal of a lithography layer 145, a metallization process, and a separation process. Each of the plurality of connecting vias connects one of the plurality of first metal lines 116 located at a first level to one of the plurality of second metal lines 155C, 155D located at a another/second level, the first level and the second level being different levels. More specifically, FIG. 11 illustrates the process stage after forming a first connecting via 155V1 in an ideal alignment scenario and forming a second connecting via 155V2 in a misalignment scenario between two of the plurality of metal lines 116 located at the first level with two of the plurality of metal lines 155C, 155D located at another/second level, or any level different from the plurality of metal lines 116 located at the first level.

The metallization process forms the connecting via 155V1 that connects the metal line 116C of the first level (one of the plurality of first metal lines located at a first level) with the metal line 155C of the other level (one of the plurality of second metal lines located at a second level), the connecting via 155V1 being formed in an ideal alignment scenario. The metallization process also forms the connecting via 155V2 that connects the metal line 116D of the first level (one of the plurality of first metal lines located at the first level) with the metal line 155D of the other level (one of the plurality of second metal lines located at a second level), the connecting via 155V2 being formed in a misalignment scenario.

The connecting via 155V1 is in contact with a top surface of the metal line 116C and extends down the sidewalls of the metal line 116C, as emphasized by dashed box 216. The connecting via 155V1 includes a horizontal section and trench extenders. The horizontal section has an hourglass shape/profile and is located on top of the first metal line 116C of the first level. The upper portion of the hourglass shape/profile of the connecting via 155V1 is emphasized by dashed boxes 255W1, 255W2, which in combination form the upper level of the connecting via 155V1. The width/later dimensions of both sides of a central axis (A1) of the upper portion of the connecting via 155V1 are equal or similar in width, as emphasized by dashed boxes 255W1, 255W2. The trench extenders 216E (e.g., via extenders), extend down to the top of the dielectric liner 125 extending up the sidewalls of metal line 116C, emphasized by bracket 216C.

The connecting via 155V2 is in contact with a top surface of the metal line 116D and extends down the sidewalls of the metal line 116D, as emphasized by dashed box 218. The connecting via 155V2 includes an upper horizontal section, a lower horizontal section, and trench extenders 218E. The lower horizontal section is located on top of the metal line 116D of the first level. The trench extenders 218E extend from the lower horizontal section of the connecting via 155V2 to the top of the dielectric liner 125 extending up the sidewalls of the metal line 116D, as emphasized by 218C. The upper horizontal section is located on top of the lower horizontal section. The upper horizontal section has a first width 255W3 located on a first side of a central axis (A2) and a second width 255W4 located on a second side of the central axis (A2), wherein the first width 255W3 is different than the second width 255W4. Although FIG. 11 depicts a wider first width 255W3 in comparison to the second width 255W4 in other embodiments the second width 255W4 may be wider than the first width 255W3.

By having the trench extenders 216E of the connecting via 155V1 and the trench extenders 218E of the connecting via 155V2 wrap around and extend down the sidewalls of the metal line 116C and metal line 116D respectively, the surface contact between the connecting vias 155V1, 155V2, and the metal lines 116C, 116D, is increased when compared to a via just connecting a top surface of a metal line. The increased surface contact between the connecting vias 155V1, 155V2, and the metal lines 116C, 116D, enables a higher current flow and lower resistance between the plurality of metal lines 116C, 116D of the first level and the plurality of metal lines 155C, 155D of the other/second level.

As described above in the discussion of FIGS. 9A/9B, the manufacturing process can lead to variations to the length/depth/height/dimension of the trench extenders 216E/218E (e.g., the amount of dielectric liner 125 that is removed, via extenders). Accordingly, the length/depth/height/dimension of the downwards extending fingers (the trench extenders/via extenders 216E/218E following metallization) of the connecting vias 155V1/155V2, as emphasized by brackets 216E/218E, may vary within each of the connecting vias 155V1/155V2, on each side of the plurality of metal lines 116, 116C, 116D located at the first level, between different connecting vias 155, or any combination thereof.

The connecting via 155V1 connects metal line 116C located on a lower level/first level with the metal line 155C located on an upper level/second level. The connecting via 155V2 connects metal line 116D located on a lower level/first level with the metal line 155D located on an upper level/second level. The conductive metal utilized for the metal line 155C, 155D, 155E of the upper level may be the same or different than the conductive metal utilized in the metal lines 116, 116C, 116D. The metal line 155C and the metal line 155D were formed from a common metal layer that was separated into multiple metal lines (e.g., metal lines 155C, 155D). A dielectric separator 141A is located between the metal lines 155E and 155C of the second level. The alignment of the dielectric separator 141A determines the overlay of the tips of the metal lines 155E, 155C and one of underlying hardmask layers 120, as emphasized by dashed box 221. FIG. 11 illustrates where the dielectric separator 141A is properly aligned, such that tips of the metal lines 155E, 155C are spaced apart from the hardmask 120, as emphasized by dashed box 221. The dielectric separator 141B is located between the metal lines 155C and 155D of the second level. The alignment of the dielectric separator 141B determines the overlay of the tips of the metal lines 155C, 155D and one of underlying hardmask layers 120, as emphasized by dashed box 225. FIG. 11 illustrates where the dielectric separator 141B misaligned, such that tips of the metal lines 155D overlaps with the hardmask 120 and the metal lines 155C are spaced apart from the hardmask, as emphasized by dashed box 225. Although FIG. 11 depicts an ideal alignment scenario with a properly aligned dielectric separator 141A and a misalignment scenario with a misaligned dielectric separator 141B, the present invention contemplates other combinations of alignments for the connecting vias and dielectric separators.

For illustrative purposes, FIG. 11 of the present invention illustrates a microelectronic interconnect structure that includes two connecting vias, one of the connecting vias 155V1 illustrating an ideal alignment scenario and one of the connecting vias 155V2 illustrating a misalignment scenario. While the figures only illustrate two connecting vias 155V1, 155V2 this is not meant to be seen as limiting the present invention. The microelectronic interconnect structure can be comprised of any number of connecting vias in various combinations of ideal alignment and misalignment scenarios and varying degrees of alignment or misalignment between the connecting vias. For example, the microelectronic interconnect structure can be comprised of all ideal alignment connecting vias, all misalignment connecting vias, and/or any number of ideal alignment connecting vias and any number of misalignment connecting vias.

While the figures illustrate a microelectronic interconnect structure illustrates two metal lines of a first level, two metal lines of a second level, and two via connections connecting a first metal line of the of the first level with a first metal line of a second level and a second metal line of the first level with a second metal line of the second level any number of various changes in form and details may be made without departing from the spirit and score of the present invention. The microelectronic interconnect structure can be comprised of any number of levels, any number of metal lines, and any number of connecting vias connecting the metal lines between the any number of levels. Additionally, the connecting vias may have a horizontal section, a lower horizontal section, and/or an upper horizontal section with varying widths on each side of a reference axis extending vertically through the center of the metal line. Furthermore, a value of a depth for each of the trench extenders associated with each of the plurality of via connections may be substantially equal to each other, different from each other, or any combination thereof; within a single via connection or across any number of a plurality of via connections. It will be understood by those skilled in the art that various changes in form and details may be made therein without departing from the spirit and scope of the present invention as defined by the appended claims and their equivalents.

A microelectronic interconnect structure that includes, a first metal line 116A located at a first level, a second metal line 155B located at a second level, wherein the first level and the second level are different levels, and a connecting via 155V that connects the first metal line 116A to the second metal line 155B, wherein the connecting via 155V includes a horizontal section 235W1, 235W2 and trench extenders 215M1, 215M2, wherein the horizontal section 235W1, 235W2 is located on top of the first metal line 116A, and the trench extenders 215M1, 215M2, extend down sidewalls of the first metal line 116A.

The horizontal section of the connecting via 155V has an hourglass shape when viewed from a vertical cross-section perspective that is perpendicular to the direction of the first metal line 116A.

The horizontal section of the connecting via 155V includes a first horizontal portion 235W1 located on a first side of a reference axis (A). The horizontal section of the connecting via 155V includes a second horizontal portion 235W2 located on a second side of a reference axis (A).

The first trench extender 215M1 is located on a first side of the first metal line 116A and extends downwards to a first depth, and a second trench extender 215M2 located on a second side of the first metal line 116A extends downwards to a second depth.

The value of the first depth of the first trench extender 215M1 is substantially equal to the value of the second depth of the second trench extender 215M2.

The value of the first depth of the first trench extender 215M1 is different from the value of the second depth of the second trench extender 215M2.

A dielectric liner 125 extends up the sidewalls of the first metal line 116A. The bottom surface of the trench extenders 215M1, 215M2, is in contact with a top surface of the dielectric liner 125.

A microelectronic interconnect structure that includes, a first metal line 116B located at a first level, a second metal line 155B located at a second level, wherein the first level and the second level are different levels, and a connecting via 155V that connects the first metal line to the second metal line, wherein the connecting via 155V includes a lower horizonal section, a upper horizontal section 245W1, 245W2, and trench extenders 217M1, 217M2, wherein the lower horizontal section is located on top of the first metal line 116B, wherein the trench extenders 217M1, 217M2 extend down sidewalls of the first metal line 116B, wherein the upper horizontal section 245W1, 245W2 is located on the lower horizontal section, wherein the upper horizontal section 245W1, 245W2 has a first width 245W1 located on a first side of a reference axis (A), wherein the reference axis (A) is located vertically through the center of the first metal line 116B, wherein the upper horizontal section has a second width 245W2 located on a second side of a reference axis (A), and wherein the first width 245W1 and the second width 245W2 are different.

The first trench extender 217M1 is located on a first side of the first metal line 116B extends downward to a first depth. The second trench extender 214M2 located on a second side of the first metal line 116B extends downward to a second depth.

A value of the first depth of the first trench extender 217M1 is substantially equal to the value of the second depth of the second trench extender 217M2.

A value of the first depth of the first trench extender 217M1 is different from the value of the second depth of the second trench extender 217M2.

A dielectric liner 125 that extends up the sidewalls of the first metal line 116B. The bottom surface of the trench extenders 217M1, 217M2 in contact with a top surface of the dielectric liner 125.

A microelectronic interconnect structure that includes, a plurality of lower metal lines 116, 116C, 116D located at a first level, a plurality of upper metal lines 155C, 155D, 155E located at a second level, wherein the first level and the second level are different levels, and a plurality of connecting vias 155V, 155V1, 155V2 where each of the plurality of connecting via 155V, 155V1, 155V2 connects one of the plurality of the first metal lines 116, 116C, 116D to one of the plurality of the second metal lines 155C, 155D, 155E, wherein each of the plurality of connecting vias includes a horizonal section 255W1, 255W2, 255W3, 255W4 and trench extenders 216E, 218E, wherein the trench extenders 216E, 218E for each of the plurality of connecting via extends down sidewalls of each of the plurality of lower metal lines 116, 116C, 116D, respectively.

The first connecting via 155V1 of the plurality of connecting vias 155V connects to a first metal line 116C of the plurality of lower metal lines 116. The horizontal section 255W1, 255W2, of the first connecting via 155V1 of the plurality of connecting vias 155V includes a first horizontal segment 255W1 located on a first side of a first reference axis (A1) and a second horizontal segment 255W2 located on a second side of the first reference axis (A1). The first reference axis (A1) extends vertically through the center of the first metal line 116C of the plurality of lower metal lines 116. The width of the first horizontal segment 255W1 is substantially equal to a width of the second horizontal segment 255W2. The second connecting via 155V2 of the plurality of connecting vias 155V connects to a first metal line 116D of the plurality of lower metal lines 116. The horizontal section 255W3, 255W4, of the second connecting via 155V2 of the plurality of connecting vias 155V includes a third horizontal segment 255W3 located on a first side of a second reference axis (A2) and a second horizontal segment 255W4 located on a second side of the second reference axis (A2). The second reference axis (A2) extends vertically through the center of the first metal line 116D of the plurality of lower metal lines 116. The width of the third horizontal segment 255W3 is substantially equal to a width of the fourth horizontal segment 255W4. A first trench extender 216E on a first side of the first metal line 116C of the plurality of lower metal lines 116 extends to a first depth. A second trench extender (not labeled) located on a second side of the first metal line 116C of the plurality of lower metal lines 116 extends to a second depth. A third trench extender 218E on a first side of the second metal line 116D of the plurality of lower metal lines 116 extends to a third depth. A fourth trench (not labeled) on a second side of the second metal line 116D of the plurality of lower metal lines 116 extends to a fourth depth.

A value for each of the first depth, the second depth, the third depth, and the fourth depth can be substantially equal to each other, different from each other, or a combination there of.

The first connecting via 155V1 of the plurality of connecting vias 155V connects to a first metal line 116C of the plurality of lower metal lines 116. The horizontal section 255W1, 255W2, of the first connecting via 155V1 of the plurality of connecting vias 155V includes a first horizontal segment 255W1 located on a first side of a first reference axis (A1) and a second horizontal segment 255W2 located on a second side of the first reference axis (A1). The first reference axis (A1) extends vertically through the center of the first metal line 116C of the plurality of lower metal lines 116. The width of the first horizontal segment 255W1 is substantially equal to a width of the second horizontal segment 255W2. The second connecting via 155V2 of the plurality of connecting vias 155V connects to a first metal line 116D of the plurality of lower metal lines 116. The horizontal section 255W3, 255W4, of the second connecting via 155V2 of the plurality of connecting vias 155V includes a third horizontal segment 255W3 located on a first side of a second reference axis (A2) and a second horizontal segment 255W4 located on a second side of the second reference axis (A2). The second reference axis (A2) extends vertically through the center of the first metal line 116D of the plurality of lower metal lines 116. The width of the third horizontal segment 255W3 is different from the width of the fourth horizontal segment 255W4.

A value for each of the first depth, the second depth, the third depth, and the fourth depth can be substantially equal to each other, different from each other, or a combination there of.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic interconnect structure comprising:
a first metal line located at a first level;
a second metal line located at a second level, wherein the first level and the second level are different levels; and
a connecting via that connects the first metal line to the second metal line, wherein the connecting via includes a horizonal section and trench extenders, wherein the horizontal section is located on top of the first metal line, and the trench extenders extend down sidewalls of the first metal line.

2. The microelectronic interconnect structure of claim 1, wherein the horizontal section of the connecting via has an hourglass shape when viewed from a vertical cross-section perspective that is perpendicular to the direction of the first metal line.

3. The microelectronic interconnect structure of claim 2, wherein the horizontal section of the connecting via includes a first horizontal portion located on a first side of a reference axis, wherein the horizontal section of the connecting via includes a second horizontal portion located on a second side of the reference axis, wherein the first horizontal portion and the second horizontal portion have the same dimensions, and wherein the reference axis extends vertically through the center of the first metal line.

4. The microelectronic interconnect structure of claim 1, wherein a first trench extender located on a first side of the first metal line extends downward to a first depth, wherein a second trench extender located on a second side of the first metal line extends downwards to a second depth.

5. The microelectronic interconnect structure of claim 4, wherein a value of the first depth is substantially equal to a value of the second depth.

6. The microelectronic interconnect structure of claim 4, wherein a value for each of the first depth and the second depth are different.

7. The microelectronic interconnect structure of claim 1, further comprises:
a dielectric liner that extends up the sidewalls of the first metal line, wherein a bottom surface of the trench extenders is in contact with a top surface of the dielectric liner.

8. A microelectronic interconnect structure comprising:
a first metal line located at a first level;
a second metal line located at a second level, wherein the first level and the second level are different levels; and
a connecting via that connects the first metal line to the second metal line, wherein the connecting via includes a lower horizonal section, a upper horizontal section, and trench extenders, wherein the lower horizontal section is located on top of the first metal line, wherein the trench extenders extend down sidewalls of the first metal line, wherein the upper horizontal section is located on the lower horizontal section, wherein the upper horizontal section has a first width located on a first side of a reference axis, wherein the reference axis is located vertically through the center of the first metal line, wherein the upper horizontal section has a second width located on a second side of a reference axis, and wherein the first width and the second width are different.

9. The microelectronic interconnect structure of claim 8, wherein a first trench extender located on a first side of the first metal line extends downward to a first depth, wherein a second trench extender located on a second side of the first metal line extends downwards to a second depth.

10. The microelectronic interconnect structure of claim 9, wherein a value of the first depth is substantially equal to a value of the second depth.

11. The microelectronic interconnect structure of claim 9, wherein a value for each of the first depth and the second depth are different.

12. The microelectronic interconnect structure of claim 8, further comprises:
a dielectric liner that extends up the sidewalls of the first metal line, wherein a bottom surface of the trench extenders is in contact with a top surface of the dielectric liner.

13. A microelectronic interconnect structure comprising:
a plurality of lower metal lines located at a first level;
a plurality of upper metal lines located at a second level, wherein the first level and the second level are different levels; and
a plurality of connecting vias where each of the plurality of connecting via connects one of the plurality of the first metal lines to one of the plurality of the second metal lines, wherein each of the plurality of connecting vias includes a horizonal section and trench extenders, wherein the trench extenders for each of the plurality of connecting via extends down sidewalls of each of the plurality of lower metal lines, respectively.

14. The microelectronic interconnect structure of claim 13, wherein a first connecting via of the plurality of connecting vias connects to a first metal line of the plurality of lower metal lines, wherein the horizontal section of the first connecting via of the plurality of connecting vias includes a first horizontal segment located on a first side of a first reference axis and a second horizontal segment located on a second side of the first reference axis, wherein the first reference axis extends vertically through the center of the first metal line of the plurality of lower metal lines, and wherein a width of the first horizontal segment is substantially equal to a width of the second horizontal segment.

15. The microelectronic interconnect structure of claim 14, wherein a second connecting via of the plurality of connecting vias connects to a second metal line of the plurality of lower metal lines, wherein the horizontal section of the second connecting via of the plurality of connecting vias includes a third horizontal segment located on a first side of a second reference axis and a fourth horizontal segment located on a second side of the second reference axis, wherein the second reference axis extends vertically through the center of the second metal line of the plurality of lower metal lines, and wherein a width of the third horizontal segment is substantially equal to a width of the fourth horizontal segment.

16. The microelectronic interconnect structure of claim 15, wherein a first trench extender located on a first side of the first metal line of the plurality of lower metal lines extends to a first depth, wherein a second trench extender located on a second side of the first metal line of the plurality of lower metal lines extends to a second depth, wherein a third trench extender located on a first side of the second metal line of the plurality of lower metal lines extends to a third depth, and wherein a fourth trench extender located on a second side of the second metal line of the plurality of lower metal lines extends to a fourth depth.

17. The microelectronic interconnect structure of claim 15, wherein a value for each of the first depth, the second depth, the third depth, and the fourth depth are substantially equal to each other.

18. The microelectronic interconnect structure of claim 15, wherein a value for each of the first depth, the second depth, the third depth, and the fourth depth can be substantial equal to each other, different from each other, or a combination there of.

19. The microelectronic interconnect structure of claim 14, wherein a second connecting via of the plurality of connecting vias connects to a second metal line of the plurality of lower metal lines, wherein the horizontal section of the second connecting via of the plurality of connecting vias includes a third horizontal segment located on a first side of a second reference axis and a fourth horizontal segment located on a second side of the second reference axis, wherein the second reference axis extends vertically through the center of the second metal line of the plurality of lower metal lines, and wherein a width of the third horizontal segment is different from a width of the fourth horizontal segment.

20. The microelectronic interconnect structure of claim 19, wherein a first trench extender located on a first side of the first metal line of the plurality of lower metal lines extends to a first depth, wherein a second trench extender located on a second side of the first metal line of the plurality of lower metal lines extends to a second depth, wherein a third trench extender located on a first side of the second metal line of the plurality of lower metal lines extends to a third depth, wherein a fourth trench extender located on a second side of the second metal line of the plurality of lower metal lines extends to a fourth depth, wherein a value for each of the first depth, the second depth, the third depth, and the fourth depth can be substantial equal to each other, different from each other, or a combination there of.
